(19) United States
(12) Patent Application Publication
(10) Pub. No.: US 2026/0181833 A1
(43) Pub. Date: Jun. 25, 2026

(54) SERVER NODE, SERVER, AND DATA CENTER

(71) Applicant: Douyin Vision Co., Ltd., Beijing (CN)

(72) Inventors: Shiqiang Li, Beijing (CN); Jian Wang, Beijing (CN); Pengbo Duan, Beijing (CN); Chaochao Li, Beijing (CN); Chenghua Liu, Beijing (CN); Yuanlin Ren, Beijing (CN)

(21) Appl. No.: 19/339,062

(22) Filed: Sep. 24, 2025

(30) Foreign Application Priority Data
Dec. 23, 2024 (CN) 202411911319.X

(51) Int. Cl. H05K 7/20

(52) U.S. Cl. CPC H05K 7/20509; H05K 7/20254; H05K 7/20272

(57) ABSTRACT

A server node, a server, and a data center are provided. The server node includes a housing, and chip units, liquid cooling modules, a liquid inlet module and a liquid outlet module which are all provided in the housing. Each chip unit includes first chips; the chip units and the liquid cooling modules are provided in one-to-one correspondence, each liquid cooling module is in heat conduction contact with the first chips in a corresponding chip unit to cool the plurality of first chips; and the liquid inlet module and the liquid outlet module are provided at intervals along a width direction of the housing, the chip units and the liquid cooling modules are located between the liquid inlet module and the liquid outlet module, and each liquid cooling module is in communication with both the liquid inlet module and the liquid outlet module.

### CROSS-REFERENCE TO RELATED APPLICATIONS

This application claims priority to Chinese Patent Application No. 202411911319.X, filed on Dec. 23, 2024, the entire disclosure of which is incorporated herein by reference as part of the present disclosure.

### TECHNICAL FIELD

The present disclosure relates to the technical field of servers, and relates to a server node, a server, and a data center.

### BACKGROUND

A server, also referred to as a servo, is a device which provides computing services and may include one or more server nodes of a computing node, a storage node, a switching node, and the like.

In order to improve the computing power density of the server under the premise of meeting the computing power compliance requirements, a plurality of chips (such as 16 chips, 32 chips and 64 chips) need to be provided in one server node. Therefore, how to achieve reasonable layout of various components of the server node in limited space is particularly important.

### SUMMARY

Embodiments of the present disclosure provide a server node, comprising: a housing, and a plurality of chip units, a plurality of liquid cooling modules, a liquid inlet module and a liquid outlet module which are all provided in the housing. Each of the plurality of chip units comprises a plurality of first chips; the plurality of chip units and the plurality of liquid cooling modules are provided in one-to-one correspondence, each of the plurality of liquid cooling modules is in heat conduction contact with the plurality of first chips in a corresponding chip unit to cool the plurality of first chips; and the liquid inlet module and the liquid outlet module are provided at intervals along a width direction of the housing, the plurality of chip units and the plurality of liquid cooling modules are located between the liquid inlet module and the liquid outlet module, and each of the plurality of liquid cooling modules is in communication with both the liquid inlet module and the liquid outlet module.

In at least one embodiment, the plurality of chip units comprise a first chip unit and a second chip unit which are arranged side by side along the width direction of the housing and form a chip set; the plurality of liquid cooling modules comprise a first liquid cooling module corresponding to the first chip unit and a second liquid cooling module corresponding to the second chip unit; and the first liquid cooling module is correspondingly provided with a first liquid conveying pipe and a first liquid discharging pipe, the second liquid cooling module is correspondingly provided with a second liquid conveying pipe and a second liquid discharging pipe, the first liquid conveying pipe connects the liquid inlet module to the first liquid cooling module, the first liquid discharging pipe connects the first liquid cooling module to the liquid outlet module, the second liquid conveying pipe connects the liquid inlet module to the second liquid cooling module, and the second liquid discharging pipe connects the second liquid cooling module to the liquid outlet module.

In at least one embodiment, the first liquid conveying pipe and the first liquid discharging pipe are provided at intervals along a length direction of the housing, and the first chip unit and the first liquid cooling module are located between the first liquid conveying pipe and the first liquid discharging pipe; and the second liquid conveying pipe and the second liquid discharging pipe are provided at intervals along the length direction of the housing, and the second chip unit and the second liquid cooling module are located between the second liquid conveying pipe and the second liquid discharging pipe.

In at least one embodiment, the first liquid conveying pipe and the second liquid conveying pipe are on a same side of the chip set, and the first liquid conveying pipe and the second liquid conveying pipe are arranged along a height direction of the housing; and the first liquid discharging pipe and the second liquid discharging pipe are on a same side of the chip set, and the first liquid discharging pipe and the second liquid discharging pipe are arranged along the height direction of the housing.

In at least one embodiment, the first liquid cooling module and the second liquid cooling module each comprise a flow shunting structure, a flow collecting structure and a plurality of first cold plates, each of the plurality of first cold plates is in heat conduction contact with at least one first chip, the flow shunting structure is in communication with a plurality of corresponding first cold plates, and the flow collecting structure is in communication with a plurality of corresponding first cold plates; the first liquid conveying pipe is connected with the flow shunting structure of the first liquid cooling module, the first liquid discharging pipe is connected with the flow collecting structure of the first liquid cooling module, the second liquid conveying pipe is connected with the flow shunting structure of the second liquid cooling module, and the second liquid discharging pipe is connected with the flow collecting structure of the second liquid cooling module; the flow shunting structure of the first liquid cooling module and the flow shunting structure of the second liquid cooling module are at a same height, and the flow shunting structure of the first liquid cooling module and the flow shunting structure of the second liquid cooling module are between the first liquid conveying pipe and the second liquid conveying pipe; and the flow collecting structure of the first liquid cooling module and the flow collecting structure of the second liquid cooling module are at a same height, and the flow collecting structure of the first liquid cooling module and the flow collecting structure of the second liquid cooling module are between the first liquid discharging pipe and the second liquid discharging pipe.

In at least one embodiment, a plurality of chip sets are provided, and the plurality of chip sets are provided side by side along a length direction of the housing.

In at least one embodiment, the plurality of chip sets comprise a first chip set and a second chip set; a first liquid conveying pipe corresponding to a first chip unit of the first chip set, a second liquid conveying pipe corresponding to a second chip unit of the first chip set, a first liquid conveying pipe corresponding to a first chip unit of the second chip set, and a second liquid conveying pipe corresponding to a second chip unit of the second chip set are all located between the first chip set and the second chip set; and a first liquid discharging pipe corresponding to the first chip unit of the first chip set and a second liquid discharging pipe corresponding to the second chip unit of the first chip set are located on a side of the first chip set facing away from the second chip set, and a first liquid discharging pipe corresponding to the first chip unit of the second chip set and a second liquid discharging pipe corresponding to the second chip unit of the second chip set are located on a side of the second chip set facing away from the first chip set.

In at least one embodiment, the liquid inlet module comprises a liquid inlet pipe, a first joint and a second joint, the first joint and the second joint are both in communication with the liquid inlet pipe, the first joint is located on a side of the first chip set, and the second joint is located on a side of the second chip set; the first liquid conveying pipe corresponding to the first chip unit of the first chip set and the second liquid conveying pipe corresponding to the second chip unit of the first chip set are both connected with a side of the first joint close to the second joint; the first liquid conveying pipe corresponding to the first chip unit of the second chip set and the second liquid conveying pipe corresponding to the second chip unit of the second chip set are both connected with a side of the second joint close to the first joint; and the liquid outlet module comprises a liquid outlet pipe and a third joint, the liquid outlet pipe is in communication with the third joint, the first liquid discharging pipe corresponding to the first chip unit of the first chip set and the second liquid discharging pipe corresponding to the second chip unit of the first chip set are both connected with a side of the third joint, and the first liquid discharging pipe corresponding to the first chip unit of the second chip set and the second liquid discharging pipe corresponding to the second chip unit of the second chip set are both connected with another side of the third joint.

In at least one embodiment, the liquid inlet module further comprises a liquid distributor, a first liquid distribution pipe and a second liquid distribution pipe, the liquid distributor is between the first joint and the second joint, the liquid inlet pipe is in communication with the liquid distributor, the liquid distributor is in communication with the first joint through the first liquid distribution pipe, and the liquid distributor is in communication with the second joint through the second liquid distribution pipe.

In at least one embodiment, each of the liquid cooling modules comprises a plurality of first cold plates, the plurality of first cold plates of each liquid cooling module are in one-to-one correspondence with the plurality of first chips of the chip unit corresponding to the each liquid cooling module, and each of the plurality of first cold plates covers a first chip corresponding to the each cold plate; the plurality of first cold plates of each of the plurality of liquid cooling modules are arranged in a plurality of cooling sets side by side along a first direction, each of the plurality of cooling sets comprises multiple first cold plates side by side along a second direction perpendicular to the first direction, the plurality of cooling sets of each of the liquid cooling modules are connected in parallel with each other, and the multiple first cold plates of each of the plurality of cooling sets are connected in series with each other; and the liquid inlet module is in communication with a first cold plate at a most upstream position in each of the plurality of cooling sets, and a first cold plate at a most downstream position in each of the plurality of cooling sets is in communication with the liquid outlet module.

In at least one embodiment, each of the plurality of liquid cooling modules comprises a flow shunting structure and a flow collecting structure, the flow shunting structure is in communication with the liquid inlet module, and the flow collecting structure is in communication with the liquid outlet module; and for each of the plurality of liquid cooling modules, the flow shunting structure and the flow collecting structure are provided at intervals along the second direction, and the plurality of cooling sets are located between the flow shunting structure and the flow collecting structure; a liquid inlet of a first cold plate closest to the flow shunting structure in each of the plurality of cooling sets is connected with the flow shunting structure through a first connecting pipe, liquid outlets and liquid inlets of two adjacent first cold plates in each of the plurality of cooling sets are connected through a second connecting pipe, and a liquid outlet of a first cold plate closest to the flow collecting structure in each of the plurality of cooling sets is connected with the flow collecting structure through a third connecting pipe.

In at least one embodiment, each of the plurality of liquid cooling modules comprises a supporting board, and each of the plurality of first cold plates is provided with a plurality of mounting lugs;

each of the plurality of mounting lugs is penetrated with a fastening bolt which is connected with the supporting board, the fastening bolt is sleeved with an elastic member, one end of the elastic member abuts against the each mounting lug, and another end of the elastic member abuts against a head of the fastening bolt; and the supporting board has an opening for exposing at least part of each of the plurality of first cold plates to enable the each first cold plate to be in heat conduction contact with a first chip corresponding to the each first cold plate.

In at least one embodiment, the server node further comprises a circuit board, a plurality of power components and a cooling structure. Each of the plurality of power components is correspondingly provided with a first chip, and the each power component is used for supplying electric energy to the first chip; the circuit board has a first surface and a second surface which are opposite to each other, the plurality of first chips are on the first surface, and the plurality of power components are on the second surface; and the cooling structure is in communication with the liquid inlet module and the liquid outlet module, and the cooling structure is in heat conduction contact with the plurality of power components to cool the plurality of power components.

In at least one embodiment, the cooling structure comprises a cooling plate and a cooling channel in the cooling plate, and the cooling plate is on a side of the power component facing away from the circuit board; the cooling plate comprises a plate body which is attached to the circuit board, and a plurality of accommodating grooves in the plate body, with openings of the plurality of accommodating grooves facing the circuit board; and the plurality of accommodating grooves are in one-to-one correspondence with the plurality of power components, and each of the plurality of power components is accommodated in an accommodating groove corresponding to the each power component, and is in heat conduction contact with a groove wall of the accommodating groove.

In at least one embodiment, the cooling channel is a serpentine channel and comprises a plurality of channel sections, and each of two opposite sides of each of plurality of the accommodating grooves is provided with a channel section.

In at least one embodiment, the server node further comprises a conductive wire, at least part of the conductive wire and the liquid inlet module are located between the plurality of chip units and a side wall of the housing; and/or, at least part of the conductive wire and the liquid outlet module are located between the plurality of chip units and the side wall of the housing.

In at least one embodiment, the server node further comprises a second chip and a second cold plate, the second chip is on a side of the plurality of chip units in a length direction of the housing, the second cold plate covers the second chip and is in heat conduction contact with the second chip, and the liquid inlet module and the liquid outlet module are both in communication with the second cold plate; and/or the server node further comprises a network card and a third cold plate, the network card is located on a side of the plurality of chip units in the length direction of the housing, the third cold plate covers the network card and is in heat conduction contact with the network card, and the liquid inlet module and the liquid outlet module are both in communication with the third cold plate; and/or the server node further comprises a circuit board and a fourth cold plate, the plurality of first chips are on the circuit board, the fourth cold plate covers at least part of the circuit board and is in heat conduction contact with the at least part of the circuit board, and the liquid inlet module and the liquid outlet module are both in communication with the fourth cold plate.

In at least one embodiment, the server node further comprises a circuit board, the circuit board comprises a chip mainboard and a power distribution board which are arranged side by side, the chip mainboard is detachably connected with the power distribution board, and the plurality of first chips are provided on the chip mainboard.

Embodiment of the present disclosure further provide a server, comprising the server node according any one of the above embodiments.

Embodiment of the present disclosure further provide a data center, comprising the above server.

### BRIEF DESCRIPTION OF DRAWINGS

The above and other features, advantages and aspects of various examples of the present disclosure will become more apparent with reference to the following specific embodiments in conjunction with the accompanying drawings. Throughout the drawings, the same or similar reference numerals indicate the same or similar elements. It should be understood that the drawings are illustrative and parts and elements are not necessarily drawn to scale. In the drawings:

FIG. 1 is a schematic diagram of a three-dimensional structure of a server node provided in an exemplary embodiment of the present disclosure;

FIG. 2 is a schematic diagram of a three-dimensional structure of a server node provided in an exemplary embodiment of the present disclosure, illustrating part of a housing;

FIG. 3 is a schematic top diagram of a server node provided in an exemplary embodiment of the present disclosure, illustrating part of a housing;

FIG. 4 is a schematic partial sectional view diagram of a server node provided in an exemplary embodiment of the present disclosure, illustrating part of the housing;

FIG. 5 is an enlarged diagram of A in FIG. 4;

FIG. 6 is a schematic exploded diagram of a server node provided in an exemplary embodiment of the present disclosure, illustrating part of a housing;

FIG. 7 is a three-dimensional partial sectional view diagram of a server node provided in an exemplary embodiment of the present disclosure;

FIG. 8 is a schematic diagram of a three-dimensional structure of a server node provided in an exemplary embodiment of the present disclosure, in which a liquid cooling module, a liquid inlet module and a liquid outlet module are not shown;

FIG. 9 is a schematic diagram of a three-dimensional structure of a liquid cooling module of a server node provided in an exemplary embodiment of the present disclosure;

FIG. 10 is a schematic top diagram of a liquid cooling module of a server node provided in an exemplary embodiment of the present disclosure;

FIG. 11 is a schematic exploded diagram of a circuit board of a server node provided in an exemplary embodiment of the present disclosure;

FIG. 12 is a schematic diagram of a three-dimensional structure of a circuit board and a first chip of a server node provided in an exemplary embodiment of the present disclosure;

FIG. 13 is a schematic diagram of a three-dimensional structure of a circuit board and a power component of a server node provided in an exemplary embodiment of the present disclosure;

FIG. 14 is a schematic diagram of a three-dimensional structure of a cooling structure of a server node provided in an exemplary embodiment of the present disclosure, in which a liquid inlet module and a liquid outlet module are shown; and

FIG. 15 is an enlarged diagram of a part B in FIG. 14.

### DESCRIPTION OF REFERENCE NUMERALS

1000—server node; 1—housing; 2—chip unit; 21—first chip; 3—liquid cooling module; 31—first liquid cooling module; 311—first liquid conveying pipe; 312—first liquid discharging pipe; 32—second liquid cooling module; 321—second liquid conveying pipe; 322—second liquid discharging pipe; 33—flow shunting structure; 331—flow shunting portion; 332—first connecting portion; 333—first connecting pipe; 334—second connecting pipe; 335—third connecting pipe; 34—flow collecting structure; 341—flow collecting portion; 342—second connecting portion; 35—first cold plate; 351—liquid inlet; 352—liquid outlet; 353—mounting lug; 354—fastening bolt; 355—elastic member; 36—cooling set; 37—supporting board; 4—liquid inlet module; 41—liquid inlet pipe; 42—first joint; 43—second joint; 44—first external joint; 441—first connecting terminal; 45—liquid distributor; 46—first liquid distribution pipe; 47—second liquid distribution pipe; 5—liquid outlet module; 51—liquid outlet pipe; 52—third joint; 53—second external joint; 531—second connecting terminal; 6—chip set; 61—first chip unit; 62—second chip unit; 63—first chip set; 64—second chip set; 7—circuit board; 71—first surface; 72—second surface; 73—chip mainboard; 74—power distribution board; 75—board-to-board connector; 8—power component; 9—cooling structure; 91—cooling plate; 911—plate body; 912—accommodating groove; 913—groove; 914—cooling pipe; 92—cooling channel; 921—serpentine runner; 922—runner section; 923—first serpentine section; 924—second serpentine section; 10—fastener; 20—conductive wire; 30—first power connector; 40—second power connector; 50—network card; 70—I/O input/output interface; 80—fan; 90—second chip; 100—second cold plate; 101—third liquid conveying pipe; 102—third liquid discharging pipe; and 110—fourth cold plate.

### DETAILED DESCRIPTION

Hereinafter, the examples of the present disclosure will be described in more detail with reference to the accompanying drawings. Although some examples of the present disclosure are shown in the accompanying drawings, it should be understood that the present disclosure may be implemented in various forms and should not be construed as being limited to the examples set forth herein; rather, these examples are provided so that the present disclosure will be understood more thoroughly and completely. It should be understood that the drawings and examples of the present disclosure are for illustrative purposes only and are not intended to limit the scope of protection of the present disclosure.

As used herein, the terms “including” and variations thereof are inclusive terms, namely, “including, but not limited to”. The term “based on” is “based, at least in part, on”. The term “one embodiment” refers to “at least one embodiment”; and the term “another embodiment” refers to “at least one additional embodiment”. Relevant definitions of other terms will be given in the description below.

It should be noted that references to the concepts such as “first” and “second” in the present disclosure are only used for distinguishing different apparatuses, modules or units, and are not intended to limit the order or interdependence of the functions executed by these apparatuses, modules or units.

It should be noted that the modification of “one” and “a plurality of” mentioned in the present disclosure is intended to be illustrative and not restrictive, and those skilled in the art will understand that they should be understood as “one or more”, unless the context clearly indicates otherwise.

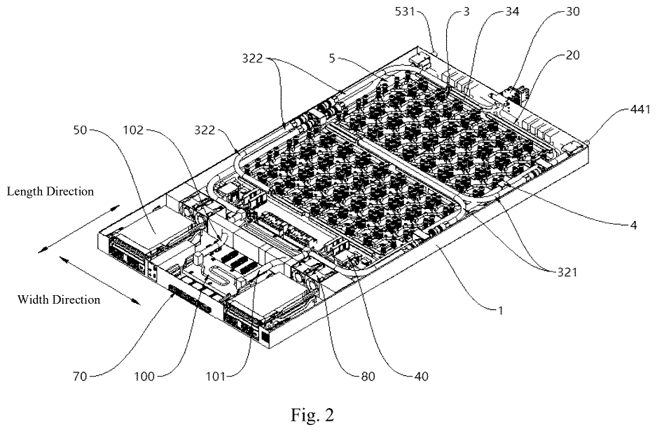

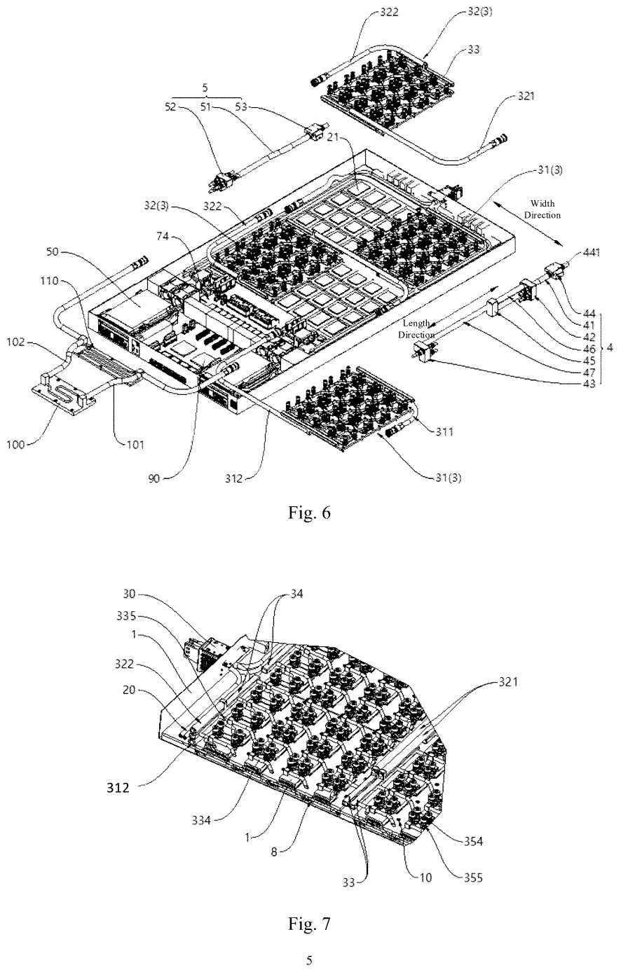

In the present disclosure, it is to be understood that the used orientation terms such as “upper and lower” are defined based on the plane directions of the accompanying drawings. They are merely for the convenience of describing the present disclosure and simplifying the description and are not intended to indicate or imply that the apparatus or element referred to must have a particular orientation, or be constructed and operated in a particular orientation, and therefore they should not be construed as limiting the present disclosure. The directional words such as “length direction” and “width direction” may be used with reference to FIG. 2 to FIG. 4, FIG. 6 and FIG. 7, and the terms “inner” and “outer” refer to the interior and exterior of a corresponding structural outline. In addition, it should be noted that the used terms such as “first” and “second” are intended to distinguish one element from another and do not have the meaning of order or importance. Additionally, in the description with reference to the drawings, like numerals in different drawings indicate like elements.

In the description of the present disclosure, it should also be noted that unless expressly specified and limited otherwise, the terms “provided”, “connected”, “connected with each other” and “mounted” should be interpreted broadly, for example, may be fixedly connected, detachably connected or integrally connected, and may be directly connected or indirectly connected through an intermediate medium. For those ordinarily skilled in the art, the specific meanings of the above terms in the present disclosure may be understood according to specific situations.

With the rapid development of information technology, a data center and a cloud computing platform have increasingly enhanced requirements for the performance of a server. In order to meet the increasingly growing data processing and storage demands, server manufacturers continually seek higher computing power density and greater computing capacity.

Constrained by the computing power compliance requirements, the computing power of a single chip is limited within a certain range. Therefore, in order to improve the computing power density and computing capacity of the server, a large number of chips are arranged in a server node. However, internal space of the server node is limited, and therefore, how to achieve reasonable layout of various components of the server node in the limited server node in the limited space is an important research direction in the field of server design and manufacturing.

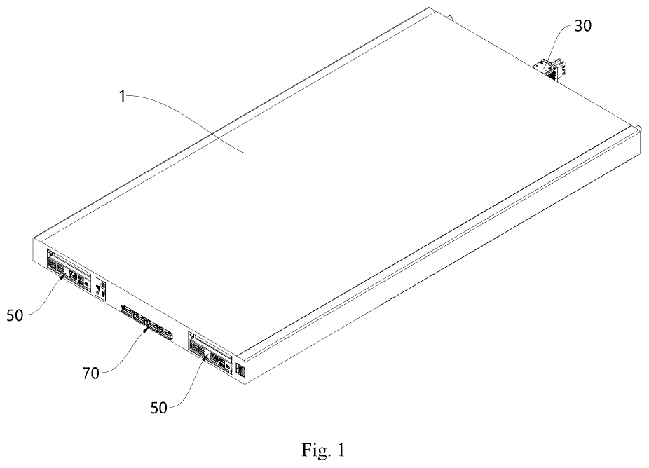

In view of this, as shown in FIG. 1 to FIG. 15, according to a first aspect of the present disclosure, a server node 1000 is provided, including a housing 1 and a plurality of chip units 2 which are all provided in the housing 1, and each of the chip units 2 includes a plurality of first chips 21.

Herein, the first chip 21 may be a chip of any suitable type, which is not limited in the present disclosure. For example, the first chip 21 may be a storage chip for storing data; and the first chip 21 may also be a communication chip for data exchange and communication with other devices. In one embodiment provided by the present disclosure, the first chip 21 may be a computing chip for processing complex mathematical and logical calculations, and the plurality of first chips 21 can improve the computing power density and computing capacity of the server node 1000.

In order to cool the first chips 21, the server node 1000 further includes a plurality of liquid cooling modules 3 provided in the housing 1, the plurality of chip units 2 and the plurality of liquid cooling modules 3 are provided in one-to-one correspondence, and each of the liquid cooling modules 3 is in heat conduction contact with the plurality of first chips 21 in the corresponding chip unit 2 to cool the first chips 21. The plurality of first chips 21 of each chip unit 2 can dissipate heat through the corresponding liquid cooling module 3 corresponding to the each chip unit 2, so that on the one hand, the running stability of the first chips 21 can be improved; and on the other hand, the overall running noise of the server node 1000 can also be reduced, thereby reducing the noise pollution of a server.

In addition, in the server node 1000 described above, the temperature of the first chip 21 which dissipates heat through the liquid cooling module 3 is relatively low, which can effectively prevent the occurrence of the situations such as poor soldering at a soldering spot of the first chip 21 due to an excessive temperature of the first chip 21 and warping deformation of the first chip 21.

The server node 1000 further includes a liquid inlet module 4 and a liquid outlet module 5 which are both provided in the housing 1, the liquid inlet module 4 and the liquid outlet module 5 are provided at intervals along a width direction of the housing 1, the plurality of chip units 2 and the plurality of liquid cooling modules 3 are located between the liquid inlet module 4 and the liquid outlet module 5, and each of the liquid cooling modules 3 is in communication with the liquid inlet module 4 and the liquid outlet module 5. The liquid inlet module 4 can enable a cooling liquid to flow into the housing 1 and distribute the cooling liquid into the plurality of liquid cooling modules 3, and the liquid outlet module 5 can collect the cooling liquid discharged from the plurality of liquid cooling modules 3 and output the cooling liquid from the housing 1.

By means of the above technical solution, since the liquid inlet module 4 and the liquid outlet module 5 are provided at intervals along the width direction of the housing 1, and the plurality of chip units 2 and the plurality of liquid cooling modules 3 are located between the liquid inlet module 4 and the liquid outlet module 5, in this way, by reasonably designing arrangement positions of the plurality of chip units 2, the liquid cooling modules 3, the liquid inlet module 4 and the liquid outlet module 5 in the housing 1, on the one hand, the plurality of chip units 2, the liquid cooling modules 3, the liquid inlet module 4 and the liquid outlet module 5 can be closely arranged in the width direction of the housing 1, thereby saving space in a length direction of the housing 1 (namely, longitudinal space of the housing 1), which is convenient to arrange other parts or components (such as a network card 50, a fan 80 and other chips) of the server node 1000 in the longitudinal space of the housing, and helps to improve the arrangement density of the components in the server node 1000 and achieve a high-density layout of the server node 1000.

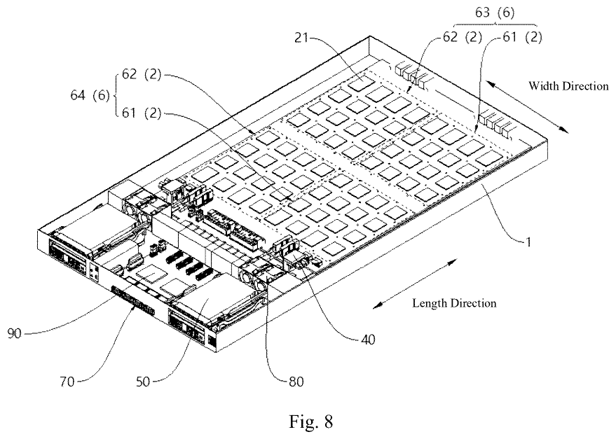

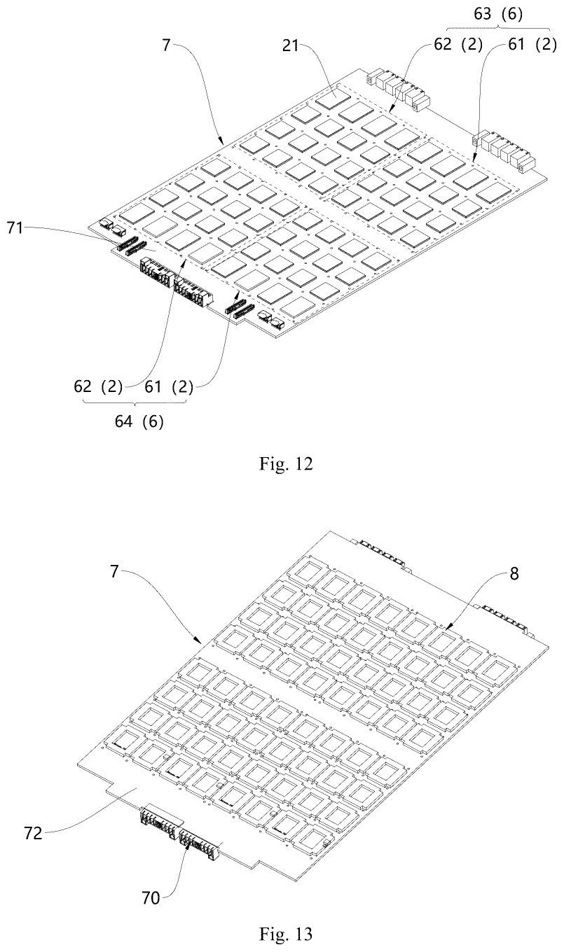

It should be noted that in the present disclosure, the plurality of chip units 2 may be arranged in any suitable arrangement mode in the housing 1, for example, the plurality of chip units 2 may be provided at intervals along the length direction and/or width direction of the housing 1, which is not limited in the present disclosure. As shown in FIG. 8 and FIG. 12, in one embodiment provided by the present disclosure, the plurality of chip units 2 are arranged in the housing 1 in a rectangular array.

In one embodiment provided by the present disclosure, as shown in FIG. 8 and FIG. 12, the above server node 1000 may include at least one chip set 6, the chip set 6 includes a first chip unit 61 and a second chip unit 62 which are arranged side by side along the width direction of the housing 1, and the plurality of chip units 2 include the first chip unit 61 and the second chip unit 62. The plurality of liquid cooling modules 3 include a first liquid cooling module 31 corresponding to the first chip unit 61 and a second liquid cooling module 32 corresponding to the second chip unit 62. The first liquid cooling module 31 is correspondingly provided with a first liquid conveying pipe 311 and a first liquid discharging pipe 312, the second liquid cooling module 32 is correspondingly provided with a second liquid conveying pipe 321 and a second liquid discharging pipe 322, the first liquid conveying pipe 311 is in communication with the liquid inlet module 4 and the first liquid cooling module 31, the first liquid discharging pipe 312 is in communication with the first liquid cooling module 31 and the liquid outlet module 5, the second liquid conveying pipe 321 is in communication with the liquid inlet module 4 and the second liquid cooling module 32, and the second liquid discharging pipe 322 is in communication with the second liquid cooling module 32 and the liquid outlet module 5. The first chip unit 61 and the second chip unit 62 are provided side by side along the width direction of the housing 1, which can achieve the close arrangement of the plurality of first chips 21 in the width direction of the housing 1. The first liquid conveying pipe 311 and the second liquid conveying pipe 321 can achieve fluid communication between the liquid inlet module 4 and the first liquid cooling module 31 as well as the second liquid cooling module 32, and the first liquid discharging pipe 312 and the second liquid discharging pipe 322 can achieve fluid communication between the first liquid cooling module 31 and the second liquid cooling module 32 and the liquid outlet module 5.

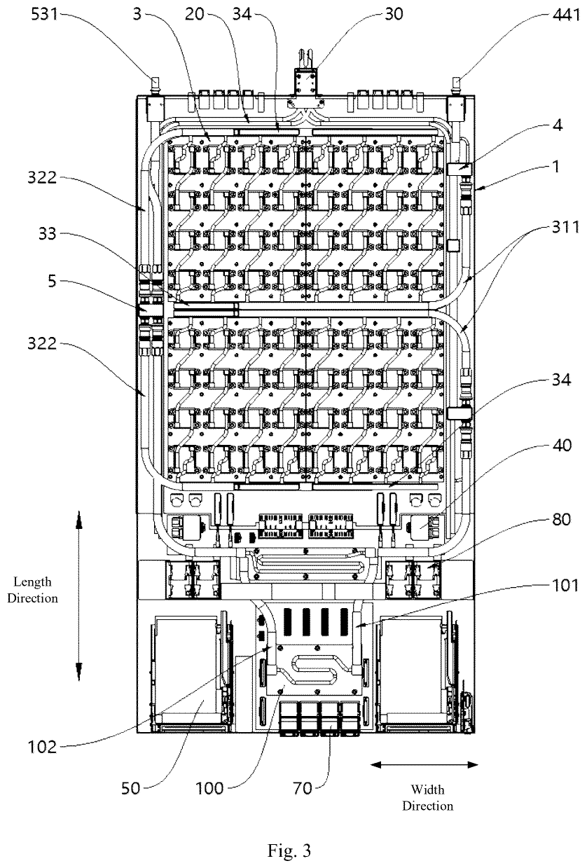

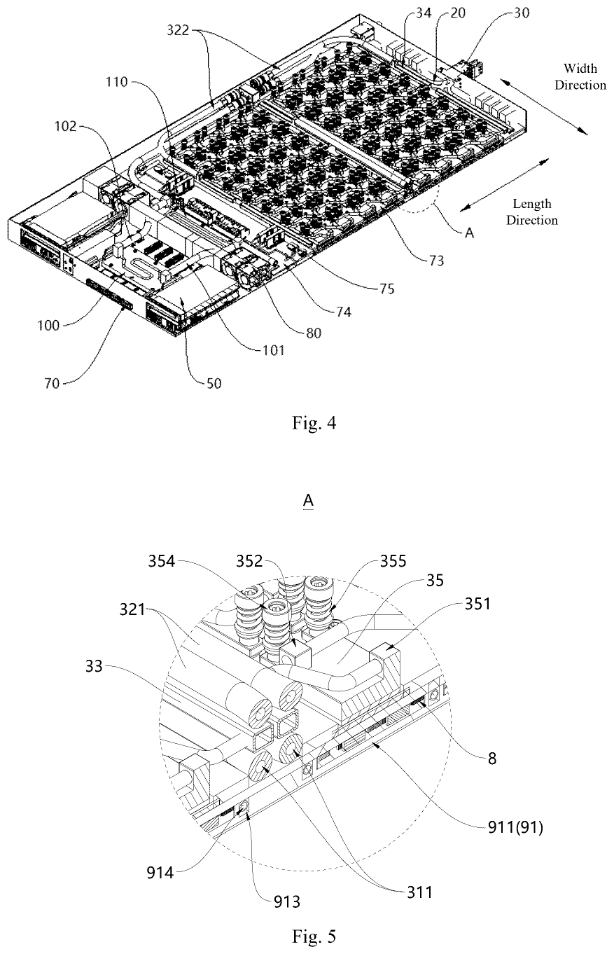

A specific positional relationship between the first liquid conveying pipe 311 and the first liquid discharging pipe 312 and the first liquid cooling module 31 is not limited in the present disclosure. As one embodiment of the present disclosure, as shown in FIG. 3, FIG. 4 and FIG. 6, the first liquid conveying pipe 311 and the first liquid discharging pipe 312 are provided at intervals along the length direction of the housing 1, and the first chip unit 61 and the first liquid cooling module 31 are located between the first liquid conveying pipe 311 and the first liquid discharging pipe 312. In other words, the first liquid conveying pipe 311 and the first liquid discharging pipe 312 are respectively provided on two sides of the first liquid cooling module 31 along the length direction of the housing 1, in this way, the first liquid conveying pipe 311 and the first liquid discharging pipe 312 can be connected with the liquid inlet module 4 and the liquid outlet module 5 without crossing the first liquid cooling module 31. In other embodiments, the first liquid conveying pipe 311 and the first liquid discharging pipe 312 described above may also be provided on the same side of the first liquid cooling module 31. It should be noted that FIG. 6 is a schematic exploded diagram of a server node provided in an embodiment of the present disclosure, which exemplarily illustrates two chip sets including four chip units, and four cooling modules 3 corresponding to the four chip units. For clarity of illustration, a first liquid cooling module 31 corresponding to the first chip unit in one chip set and a second liquid cooling module 32 corresponding to the second chip unit in another chip set are shown in an explode view.

A specific positional relationship between the second liquid conveying pipe 321 and the second liquid discharging pipe 322 and the second liquid cooling module 32 is also not limited in the present disclosure. As one embodiment of the present disclosure, as shown in FIG. 3, FIG. 4 and FIG. 6, the second liquid conveying pipe 321 and the second liquid discharging pipe 322 are respectively provided on two sides of the second liquid cooling module 32 along the length direction of the housing 1. In other words, the second liquid conveying pipe 321 and the second liquid discharging pipe 322 are respectively provided on two sides of the second liquid cooling module 32 along the length direction of the housing 1, and the second liquid conveying pipe 321 and the second liquid discharging pipe 322 can be connected with the liquid inlet module 4 and the liquid outlet module 5 without crossing the second liquid cooling module 32. In other embodiments, the second liquid conveying pipe 321 and the second liquid discharging pipe 322 described above may also be provided on the same side of the second liquid cooling module 32.

Optionally, as shown in FIG. 3 to FIG. 6, the first liquid conveying pipe 311 and the second liquid conveying pipe 321 are located on the same side of the chip set 6, and the first liquid conveying pipe 311 and the second liquid conveying pipe 321 are arranged along a height direction of the housing 1, in other words, in the height direction of the housing 1, the first liquid conveying pipe 311 and the second liquid conveying pipe 321 are at least partially overlapped. The first liquid conveying pipe 311 and the second liquid conveying pipe 321 are arranged along the height direction of the housing 1, which causes less occupied space in the length direction of the housing 1, and is conducive to further saving the space in the length direction of the housing 1, thereby helping to arrange other components in the server node 1000 in the length direction of the housing 1, and improving the layout density of various components in the server node 1000, and helpful in achieving the high-density layout.

Optionally, as shown in FIG. 3 to FIG. 6, the first liquid discharging pipe 312 and the second liquid discharging pipe 322 are located on the same side of the chip set 6, and the first liquid discharging pipe 312 and the second liquid discharging pipe 322 are arranged along the height direction of the housing 1. That is, the first liquid discharging pipe 312 and the second liquid discharging pipe 322 are at least partially overlapped in the height direction of the housing 1. The first liquid discharging pipe 312 and the second liquid discharging pipe 322 are arranged along the height direction of the housing 1, which causes less occupied space in the length direction of the housing 1, and is conducive to further saving the space in the length direction of the housing 1, thereby helping to arrange other components in the server node 1000 in the length direction of the housing 1, and improving the layout density of various components in the server node 1000, and helpful in achieving the high-density layout.

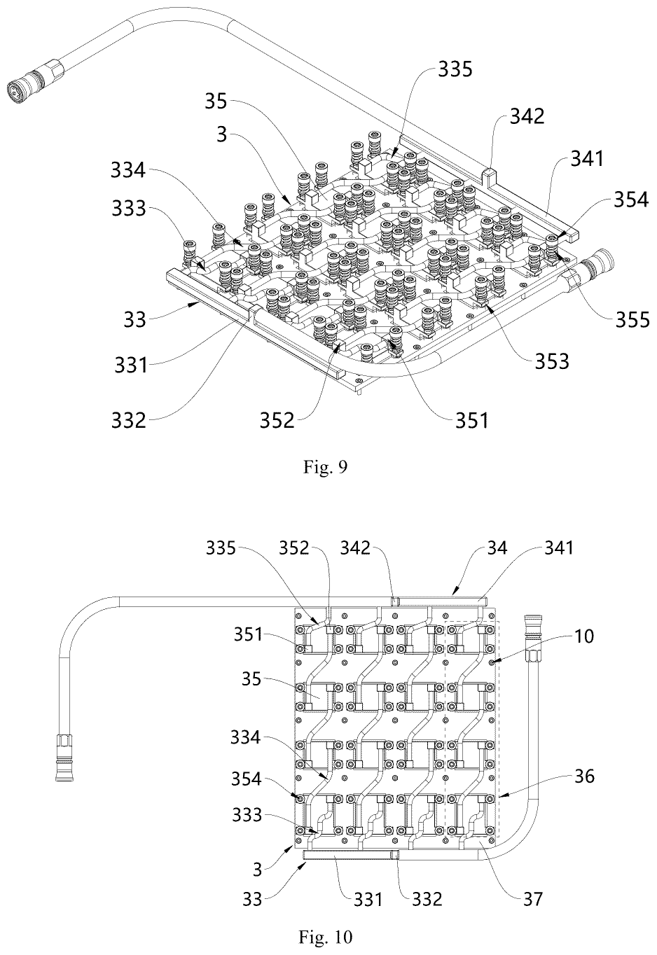

In the present disclosure, the first liquid cooling module 31 and the second liquid cooling module 32 may have any suitable structure as long as the first liquid cooling module 31 and the second liquid cooling module 32 can satisfy the heat dissipation requirements of the first chip unit 61 and the second chip unit 62, respectively. As one embodiment of the present disclosure, as shown in FIG. 2 to FIG. 7, FIG. 9 and FIG. 10, the first liquid cooling module 31 and the second liquid cooling module 32 each include a flow shunting structure 33, a flow collecting structure 34 and a plurality of first cold plates 35, each of the first cold plates 35 is in heat conduction contact with at least one first chip 21, each of the flow shunting structures 33 is in communication with a plurality of corresponding first cold plates 35, each of the flow collecting structures 34 is in communication with a plurality of corresponding first cold plates 35, the first liquid conveying pipe 311 is connected with the flow shunting structure 33 of the first liquid cooling module 31, the first liquid discharging pipe 312 is connected with the flow collecting structure 34 of the first liquid cooling module 31, the second liquid conveying pipe 321 is connected with the flow shunting structure 33 of the second liquid cooling module 32, and the second liquid discharging pipe 322 is connected with the flow collecting structure 34 of the second liquid cooling module 32.

The cooling liquid in the first liquid conveying pipe 311 or the second liquid conveying pipe 321 can be distributed into the plurality of first cold plates 35 through the flow shunting structure 33, so as to prevent the first liquid conveying pipe 311 or the second liquid conveying pipe 321 from being connected with the plurality of first cold plates 35 through multiple pipelines, which helps to simplify connecting pipelines between the first liquid conveying pipe 311 or the second liquid conveying pipe 321 and the plurality of first cold plates 35. By the same reasoning, the flow collecting structure 34 can also prevent the first liquid discharging pipe 312 or the second liquid discharging pipe 322 from being connected with the plurality of first cold plates 35 through multiple pipelines, which helps to simplify connecting pipelines between the first liquid discharging pipe 312 or the second liquid discharging pipe 322 and the plurality of first cold plates 35.

Optionally, as shown in FIG. 2 to FIG. 6, the first liquid conveying pipe 311, the second liquid conveying pipe 321, the flow shunting structure 33 of the first liquid cooling module 31 and the flow shunting structure 33 of the second liquid cooling module 32 are located on the same side of the chip set 6, the first liquid conveying pipe 311, the second liquid conveying pipe 321, and the flow shunting structure 33 of the first liquid cooling module 31 are arranged along the height direction of the housing 1, and the first liquid conveying pipe 311, the second liquid conveying pipe 321, and the flow shunting structure 33 of the second liquid cooling module 32 are arranged along the height direction of the housing 1. The first liquid discharging pipe 312, the second liquid discharging pipe 322, the flow collecting structure 34 of the first liquid cooling module 31 and the flow collecting structure 34 of the second liquid cooling module 32 are located on the same side of the chip set 6, the first liquid discharging pipe 312, the second liquid discharging pipe 322, and the flow collecting structure 34 of the first liquid cooling module 31 are arranged along the height direction of the housing 1, and the first liquid discharging pipe 312, the second liquid discharging pipe 322, and the flow collecting structure 34 of the second liquid cooling module 32 are arranged along the height direction of the housing 1.

Since the first liquid conveying pipe 311, the second liquid conveying pipe 321, and the flow shunting structure 33 of the first liquid cooling module 31 are arranged along the height direction of the housing 1, the first liquid conveying pipe 311, the second liquid conveying pipe 321, and the flow shunting structure 33 of the second liquid cooling module 32 are also arranged along the height direction of the housing 1, thus, the first liquid conveying pipe 311, the second liquid conveying pipe 321 and the flow shunting structure 33 constitute a three-layer pipeline design in the height direction of the housing 1, so that the space occupied by the first liquid conveying pipe 311, the second liquid conveying pipe 321 and the flow shunting structure 33 in the length direction of the housing 1 can be reduced, thereby being conducive to further saving the space in the length direction of the housing 1, and thus being convenient to arrange other components in the server node 1000.

By the same reasoning, since the first liquid discharging pipe 312, the second liquid discharging pipe 322, and the flow collecting structure 34 of the first liquid cooling module 31 are arranged along the height direction of the housing 1, the first liquid discharging pipe 312, the second liquid discharging pipe 322, and the flow collecting structure 34 of the second liquid cooling module 32 are also arranged along the height direction of the housing 1, thus, the first liquid discharging pipe 312, the second liquid discharging pipe 322 and the flow collecting structure 34 constitute a three-layer pipeline design in the height direction of the housing 1, so that the space occupied by the first liquid discharging pipe 312, the second liquid discharging pipe 322 and the flow collecting structure 34 in the length direction of the housing 1 can be reduced, thereby being conducive to further saving the space in the length direction of the housing 1, and thus being convenient to arrange other components in the server node 1000.

Herein, it should be noted that a corresponding relationship between the first cold plate 35 and the first chip 21 described above is not limited in the present disclosure, for example, one first cold plate 35 may be in heat conduction contact with one first chip 21, thereby dissipating heat for the first chip 21. One first cold plate 35 may also be in heat conduction contact with multiple first chips 21 simultaneously, thereby dissipating heat for the multiple first chips 21 simultaneously.

In the server node 1000 provided by the present disclosure, the first liquid conveying pipe 311, the second liquid conveying pipe 321, the flow shunting structure 33 of the first liquid cooling module 31, and the flow shunting structure 33 of the second liquid cooling module 32 may be arranged along the height direction of the housing 1 in any suitable manner, for example, the first liquid conveying pipe 311 and the second liquid conveying pipe 321 may be provided adjacent to each other, and the flow shunting structure 33 of the first liquid cooling module 31 or the second liquid cooling module 32 is provided above or below the first liquid conveying pipe 311 and the second liquid conveying pipe 321.

As one exemplary embodiment of the present disclosure, as shown in FIG. 2 to FIG. 6, the flow shunting structure 33 of the first liquid cooling module 31 and the flow shunting structure 33 of the second liquid cooling module 32 are located at the same height, and the flow shunting structure 33 of the first liquid cooling module 31 and the flow shunting structure 33 of the second liquid cooling module 32 are located between the first liquid conveying pipe 311 and the second liquid conveying pipe 321, that is, the first liquid conveying pipe 311, the second liquid conveying pipe 321 and the flow shunting structure 33 constitute a sandwich structure, and the flow shunting structure 33 is located between the first liquid conveying pipe 311 and the second liquid conveying pipe 321.

It should be noted that in the server node 1000 provided by the present disclosure, the first liquid discharging pipe 312, the second liquid discharging pipe 322, the flow collecting structure 34 of the first liquid cooling module 31, and the flow collecting structure 34 of the second liquid cooling module 32 may also be arranged along the height direction of the housing 1 in any suitable manner, for example, the first liquid discharging pipe 312 and the second liquid discharging pipe 322 may be provided adjacent to each other, and the flow collecting structure 34 of the first liquid cooling module 31 or the second liquid cooling module 32 is provided above or below the first liquid discharging pipe 312 and the second liquid discharging pipe 322.

As one exemplary embodiment of the present disclosure, as shown in FIG. 2 to FIG. 6, the flow collecting structure 34 of the first liquid cooling module 31 and the flow collecting structure 34 of the second liquid cooling module 32 are located at the same height, and the flow collecting structure 34 of the first liquid cooling module 31 and the flow collecting structure 34 of the second liquid cooling module 32 are located between the first liquid discharging pipe 312 and the second liquid discharging pipe 322. In this way, the first liquid discharging pipe 312, the second liquid discharging pipe 322 and the flow collecting structure 34 may constitute a sandwich structure, and the flow collecting structure 34 is located between the first liquid discharging pipe 312 and the second liquid discharging pipe 322.

Optionally, as shown in FIG. 7, FIG. 9 and FIG. 10, each flow shunting structure 33 includes a flow shunting portion 331 and a first connecting portion 332 in communication with each other, the first connecting portion 332 is provided on the flow shunting portion 331 and protrudes from the flow shunting portion 331 along the height direction of the housing 1, and the flow shunting portion 331 is in communication with a plurality of corresponding first cold plates 35. The first connecting portion 332 protruding from the flow shunting portion 331 along the height direction of the housing 1 can facilitate connection with the first liquid conveying pipe 311 or the second liquid conveying pipe 321.

Specifically, as shown in FIG. 7, the flow shunting portion 331 of the first liquid cooling module 31 and the flow shunting portion 331 of the second liquid cooling module 32 are located between the first liquid conveying pipe 311 and the second liquid conveying pipe 321, the first connecting portion 332 of the first liquid cooling module 31 is connected with the first liquid conveying pipe 311, the first connecting portion 332 of the second liquid cooling module 32 is connected with the second liquid conveying pipe 321, and a protruding direction of the first connecting portion 332 of the first liquid cooling module 31 is opposite to a protruding direction of the first connecting portion 332 of the second liquid cooling module 32, so that the first connecting portion 332 of the first liquid cooling module 31 can extend towards the first liquid conveying pipe 311 and be connected with the first liquid conveying pipe 311, and the first connecting portion 332 of the second liquid cooling module 32 can extend towards the second liquid conveying pipe 321 and be connected with the second liquid conveying pipe 321.

Optionally, as shown in FIG. 7, FIG. 9 and FIG. 10, each of the flow collecting structures 34 includes a flow collecting portion 341 and a second connecting portion 342 in communication with each other, wherein the second connecting portion 342 is provided on the flow collecting portion 341 and protrudes from the flow collecting portion 341 along the height direction of the housing 1, and the flow collecting portion 341 is in communication with a plurality of corresponding first cold plates 35. The second connecting portion 342 protruding from the flow collecting portion 341 along the height direction of the housing 1 can facilitate connection with the first liquid discharging pipe 312 and the second liquid discharging pipe 322.

Specifically, as shown in FIG. 7, the flow collecting portion 341 of the first liquid cooling module 31 and the flow collecting portion 341 of the second liquid cooling module 32 are located between the first liquid discharging pipe 312 and the second liquid discharging pipe 322, the second connecting portion 342 of the first liquid cooling module 31 is connected with the first liquid discharging pipe 312, the second connecting portion 342 of the second liquid cooling module 32 is connected with the second liquid discharging pipe 322, and a protruding direction of the second connecting portion 342 of the first liquid cooling module 31 is opposite to a protruding direction of the second connecting portion 342 of the second liquid cooling module 32, so that the second connecting portion 342 of the first liquid cooling module 31 can extend towards the first liquid discharging pipe 312 and be connected with the first liquid discharging pipe 312, and the second connecting portion 342 of the second liquid cooling module 32 can extend towards the second liquid discharging pipe 322 and be connected with the second liquid discharging pipe 322.

In the server node 1000 provided by the present disclosure, the number of the above chip set 6 may be one, and the number of the chip sets 6 may also be plural, which is not limited in the present disclosure, as long as the server node 1000 can satisfy the usage requirements of the server. As one embodiment of the present disclosure, as shown in FIG. 8 and FIG. 12, the number of the above chip sets 6 may be plural, and a plurality of chip sets 6 are provided side by side along the length direction of the housing 1. The plurality of chip sets 6 can enable the server node 1000 to have more chip units 2, so that the overall computing power of the server node 1000 can be improved, and the computing power density of the server node 1000 can be improved.

In order to be convenient to connect the liquid cooling modules 3 (namely, the first liquid cooling module 31 and the second liquid cooling module 32 mentioned above) corresponding to the chip units 2 (namely, the first chip unit 61 and the second chip unit 62 mentioned above) of the plurality of chip sets 6 with the liquid inlet module 4 and the liquid outlet module 5, optionally, as shown in FIG. 12, the plurality of chip sets 6 include a first chip set 63 and a second chip set 64, the first liquid conveying pipe 311 corresponding to the first chip unit 61 of the first chip set 63, the second liquid conveying pipe 321 corresponding to the second chip unit 62 of the first chip set 63, the first liquid conveying pipe 311 corresponding to the first chip unit 61 of the second chip set 64, and the second liquid conveying pipe 321 corresponding to the second chip unit 62 of the second chip set 64 are all located between the first chip set 63 and the second chip set 64. The first liquid discharging pipe 312 corresponding to the first chip unit 61 of the first chip set 63 and the second liquid discharging pipe 322 corresponding to the second chip unit 62 of the first chip set 63 are on a side of the first chip set 63 facing away from the second chip set 64, and the first liquid discharging pipe 312 corresponding to the first chip unit 61 of the second chip set 64 and the second liquid discharging pipe 322 corresponding to the second chip unit 62 of the second chip set 64 are on a side of the second chip set 64 facing away from the first chip set 63.

That is, the first liquid conveying pipe 311 and the second liquid conveying pipe 321 corresponding to each liquid cooling module 3 are both located between the first chip set 63 and the second chip set 64, while the first liquid discharging pipe 312 and the second liquid discharging pipe 322 corresponding to the first chip set 63 and the first liquid discharging pipe 312 and the second liquid discharging pipe 322 corresponding to the second chip set 64 are respectively located on two opposite sides of the plurality of chip units 2. In this way, it is possible to separate the first liquid conveying pipe 311 and the second liquid conveying pipe 321 from the first liquid discharging pipe 312 and the second liquid discharging pipe 322, and to facilitate connection of the first liquid conveying pipe 311 and the second liquid conveying pipe 321 with the liquid inlet module 4, as well as connection of the first liquid discharging pipe 312 and the second liquid discharging pipe 322 with the liquid outlet module 5.

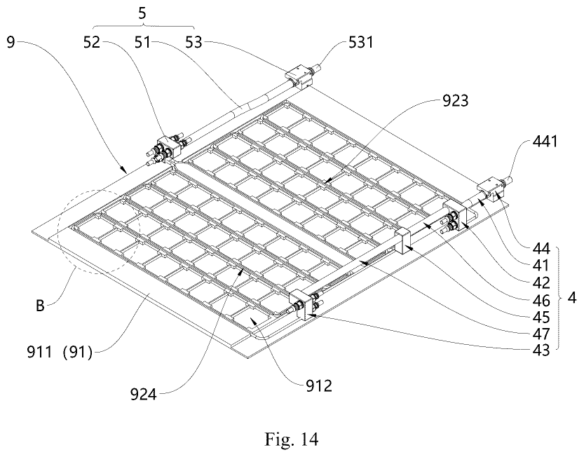

In order to enable the liquid inlet module 4 to distribute the cooling liquid to a plurality of first liquid conveying pipes 311 and a plurality of second liquid conveying pipes 321, as one embodiment of the present disclosure, referring to FIG. 3, FIG. 6 and FIG. 14 in combination, the above liquid inlet module 4 may include a liquid inlet pipe 41, a first joint 42 and a second joint 43, the first joint 42 and the second joint 43 are both in communication with the liquid inlet pipe 41, the first joint 42 is on a side of the first chip set 63, the second joint 43 is on a side of the second chip set 64, the first liquid conveying pipe 311 corresponding to the first chip unit 61 of the first chip set 63 and the second liquid conveying pipe 321 corresponding to the second chip unit 62 of the first chip set 63 are both connected with one side of the first joint 42 close to the second joint 43, and the first liquid conveying pipe 311 corresponding to the first chip unit 61 of the second chip set 64 and the second liquid conveying pipe 321 corresponding to the second chip unit 62 of the second chip set 64 are both connected with one side of the second joint 43 close to the first joint 42.

Since the first liquid conveying pipes 311 and the second liquid conveying pipes 321 corresponding to the first chip set 63 and the second chip set 64 are all between the first chip set 63 and the second chip set 64, and the first joint 42 is on the side of the first chip set 63, the second joint 43 is on the side of the second chip set 64, thus, the first liquid conveying pipe 311 and the second liquid conveying pipe 321 corresponding to the first chip set 63 may be bent towards a direction facing away from the second chip set 64 to be connected to the side of the first joint 42 close to the second joint 43, and the first liquid conveying pipe 311 and the second liquid conveying pipe 321 of the second chip set 64 may be bent towards a direction facing away from the first chip set 63 to be connected to the side of the second joint 43 close to the first joint 42, in this way, on the one hand, the flow of the cooling fluid may be prevented from being affected by excessive bending of the first liquid conveying pipe 311 and the second liquid conveying pipe 321, and on the other hand, by reasonably designing the positions of the first joint 42 and the second joint 43, the pipeline lengths of the first liquid conveying pipe 311 and the second liquid conveying pipe 321 may also be reduced.

Optionally, the above liquid inlet module 4 may further include a first external joint 44, the first external joint 44 has a first connecting terminal 441 protruding from the housing 1, the first external joint 44 is connected with the liquid inlet pipe 41, and the first connecting terminal 441 is used for being connected with a cooling liquid supply apparatus outside the housing 1.

In order to enable the cooling liquid flowing in via the liquid inlet pipe 41 to flow to the liquid cooling module 3 corresponding to the first chip set 63 and the liquid cooling module 3 corresponding to the second chip set 64 simultaneously, optionally, as shown in FIG. 6 and FIG. 14, the above liquid inlet module 4 may further include a liquid distributor 45, a first liquid distribution pipe 46 and a second liquid distribution pipe 47. The liquid distributor 45 is located between the first joint 42 and the second joint 43, the liquid inlet pipe 41 is in communication with the liquid distributor 45, the liquid distributor 45 is in communication with the first joint 42 through the first liquid distribution pipe 46, and the liquid distributor 45 is in communication with the second joint 43 through the second liquid distribution pipe 47. The liquid distributor 45 can shunt the cooling liquid flowing in via the liquid inlet pipe 41, so that the cooling liquid can flow to the liquid cooling module 3 corresponding to the first chip set 63 and the liquid cooling module 3 corresponding to the second chip set 64 simultaneously, so as to dissipate heat for the first chip set 63 and the second chip set 64.

In order to enable the cooling liquid of a plurality of first liquid discharging pipes 312 and second liquid discharging pipes 322 to converge to the liquid outlet module 5, as one embodiment of the present disclosure, as shown in FIG. 6 and FIG. 14, the liquid outlet module 5 may include a liquid outlet pipe 51 and a third joint 52, the liquid outlet pipe 51 is in communication with the third joint 52, the first liquid discharging pipe 312 corresponding to the first chip unit 61 of the first chip set 63 and the second liquid discharging pipe 322 corresponding to the second chip unit 62 of the first chip set 63 are both connected with one side of the third joint 52, and the first liquid discharging pipe 312 corresponding to the first chip unit 61 of the second chip set 64 and the second liquid discharging pipe 322 corresponding to the second chip unit 62 of the second chip set 64 are both connected with the other side of the third joint 52.

Since the first liquid discharging pipe 312 and the second liquid discharging pipe 322 corresponding to the first chip set 63 and the first liquid discharging pipe 312 and the second liquid discharging pipe 322 corresponding to the second chip set 64 are respectively on two opposite sides of the first chip set 63 and the second chip set 64, the first liquid discharging pipes 312 and the second liquid discharging pipes 322 may be gathered from two sides of the first chip set 63 and the second chip set 64 towards the middle of the first chip set 63 and the second chip set 64 to be connected to two opposite sides of the third joint 52, in this way, the number of the joints used may be reduced, and the internal space of the housing 1 may be saved.

As shown in FIG. 3, FIG. 6 and FIG. 13, the above liquid outlet module may further include a second external joint 53, the second external joint 53 has a second connecting terminal 531 protruding from the housing 1, the second external joint 53 is connected with the liquid discharging pipe 51, and the other end of the second connecting terminal 531 is suitable for being connected with an external cooling liquid recovery apparatus.

In order to enable the plurality of first chips 21 to have better cooling effects, as shown in FIG. 7, FIG. 9 and FIG. 10, each liquid cooling module 3 includes a plurality of first cold plates 35, the plurality of first cold plates 35 of each liquid cooling module 3 are in one-to-one correspondence with the plurality of first chips 21 of the chip unit 2 corresponding to the liquid cooling module 3, and each of the first cold plates 35 covers the corresponding first chip 21. In other words, each first chip 21 is correspondingly provided with a first cold plate 35, so that the plurality of first chips 21 have better heat dissipation effects.

Herein, it should be noted that a connection relationship between the plurality of first cold plates 35 in the liquid cooling module 3 is also not limited in the present disclosure, for example, the plurality of first cold plates 35 may be connected in series with each other, or the plurality of first cold plates 35 may also be connected in parallel with each other.

As one embodiment of the present disclosure, as shown in FIG. 10, each of the above liquid cooling modules 3 includes a plurality of cooling sets 36 provided side by side along a first direction, each of the cooling sets 36 includes multiple first cold plates 35 provided side by side along a second direction perpendicular to the first direction, the plurality of cooling sets 36 of each liquid cooling module 3 are connected in parallel with each other, the multiple first cold plates 35 of each cooling set 36 are connected in series with each other, the liquid inlet module 4 is in communication with the first cold plate 35 at the most upstream position in each cooling set 36, and the first cold plate 35 at the most downstream position in each cooling set 36 is in communication with the liquid outlet module 5. In other words, some first cold plates 35 of the plurality of first cold plates 35 are connected in series with each other to constitute a plurality of cooling sets 36 firstly, and then the plurality of cooling sets 36 are connected in parallel with each other, so that the cooling capacity of the cooling liquid can be reasonably utilized to avoid a waste of the cooling capacity of the cooling liquid, and the heat dissipation requirements of the first chips 21 can also be satisfied. In addition, the plurality of first cold plates 35 connected both in series and in parallel can also simplify the arrangement of connecting pipelines.

The specific directions of the above first direction and second direction are also not limited in the present disclosure, and as one embodiment of the present disclosure, the above first direction may be the width direction of the housing 1, and the second direction may be the length direction of the housing 1. In other embodiments, the above first direction may also be the length direction of the housing 1, and the second direction may also be the width direction of the housing 1.

In order to enable each of the first chips 21 to have a good heat dissipation effect, optionally, as shown in FIG. 10, the number of the first cold plates 35 connected in series in each cooling set 36 described above is 2 to 6, so that it can be ensured that the temperature of the cooling liquid flowing through the first cold plate 35 at the most downstream position in each cooling set 36 is not too high, and the first cold plate 35 at the most downstream position in the first cooling set 36 can still have a better heat dissipation effect.

It should be noted that the specific number of the first chips 21 is also not limited in the present disclosure, as long as the server node 1000 can satisfy the running requirements of the server, and as one embodiment of the present disclosure, the total number of the first chips 21 may be 16, 32 or 64, and the like.

Optionally, as shown in FIG. 7, FIG. 9 and FIG. 10, each of the above liquid cooling modules 3 includes a flow shunting structure 33 and a flow collecting structure 34, the flow shunting structure 33 is in communication with the liquid inlet module 4, and the flow collecting structure 34 is in communication with the liquid outlet module 5. The flow shunting structure 33 and the flow collecting structure 34 of each liquid cooling module 3 are provided at intervals along the second direction, and a plurality of cooling sets 36 of each liquid cooling module 3 are located between the flow shunting structure 33 and the flow collecting structure 34 of the liquid cooling module 3. The liquid inlet 351 of the first cold plate 35 closest to the flow shunting structure 33 in each cooling set 36 is connected with the flow shunting structure 33 through a first connecting pipe 333, a liquid outlet 352 and the liquid inlet 351 of two adjacent first cold plates 35 in each cooling set 36 are connected through a second connecting pipe 334, and the liquid outlet 352 of the first cold plate 35 closest to the flow collecting structure 34 in each cooling set 36 is connected with the flow collecting structure 34 through a third connecting pipe 335. By means of the first connecting pipe 333, the second connecting pipe 334 and the third connecting pipe 335, mutual connection in series among the plurality of first cold plates 35 of the cooling sets 36, and connection between the cooling sets 36 and the flow shunting structure 33 as well as the flow collecting structures 34 can be achieved.

In order to facilitate the arrangement and connection of the connecting pipes (namely, the first connecting pipe 333, the second connecting pipe 334 and the third connecting pipe 335) between the plurality of first cold plates 35, optionally, as shown in FIG. 7, FIG. 9 and FIG. 10, the liquid inlet 351 and the liquid outlet 352 of each of the above first cold plates 35 are provided at intervals along a diagonal line of the first cold plate 35, and the liquid inlet 351 and the liquid outlet 352 of the plurality of first cold plates 35 of each of the cooling sets 36 are arranged at intervals along the second direction. In this way, a plurality of first connecting pipes 333, a plurality of second connecting pipes 334 and a plurality of third connecting pipes 335 can be arranged at intervals between the plurality of first cold plates 35, and the situation of mutual interference of the plurality of first connecting pipes 333, the plurality of second connecting pipes 334 and the plurality of third connecting pipes 335 can be effectively avoided.

The shapes of the first connecting pipe 333, the second connecting pipe 334 and the third connecting pipe 335 are all not limited in the present disclosure. Optionally, bent pipes are adopted as the first connecting pipe 333, the second connecting pipe 334 and the third connecting pipe 335 described above. In this way, by reasonably designing bending angles of ends of the first connecting pipe 333, the second connecting pipe 334 and the third connecting pipe 335, the connection of the first connecting pipe 333, the second connecting pipe 334 and the third connecting pipe 335 with the liquid inlet 351 or the liquid outlet 352 can be facilitated.

The materials of the first connecting pipe 333, the second connecting pipe 334 and the third connecting pipe 335 are also not limited in the present disclosure, and as one embodiment of the present disclosure, the first connecting pipe 333, the second connecting pipe 334 and the third connecting pipe 335 described above are all made of copper. The first connecting pipe 333, the second connecting pipe 334 and the third connecting pipe 335 which are made of copper have relatively high corrosion resistance and relatively long lives.

In order to enable the first cold plate 35 to be in reliable heat conduction contact with the first chip 21, optionally, as shown in FIG. 9, each of the above liquid cooling modules 3 includes a supporting board 37, each first cold plate 35 is provided with a plurality of mounting lugs 353, and each mounting lug 353 is penetrated with a fastening bolt 354. The fastening bolt 354 is connected with the supporting board 37, each fastening bolt 354 is sleeved with an elastic member 355, one end of the elastic member 355 abuts against the mounting lug 353, the other end of the elastic member 355 abuts against a head of the fastening bolt 354, and the supporting board 37 has an opening for exposing at least part of the first cold plate 35 to enable the first cold plate 35 to be in heat conduction contact with the first chip 21.

The fastening bolt 354 mounted on the supporting board 37 can clamp the elastic member 355 between the mounting lug 353 and the head of the fastening bolt 354, in this way, on the one hand, an elastic force of the elastic member 355 can compress the first cold plate 35 on the first chip 21, so that the first cold plate 35 can be in reliable heat conduction contact with the first chip 21, and a heat dissipation effect of the first chip 21 is better, and on the other hand, a relative small elastic force of the elastic member 355 can also prevent the first cold plate 35 from being excessively stressed and damaging the first chip 21. In other words, by providing the elastic member 355 to abut against the first cold plate 35, it can facilitate the adjustment of an abutting force between the first cold plate 35 and the first chip 21, so that a contact area between the first cold plate 35 and the first chip 21 can be secured, and the damage to the first chip 21 can also be avoided.

In order to prevent the first connecting pipe 333, the second connecting pipe 334 and the third connecting pipe 335 from falling off the first cold plate 35 when the first cold plate 35 floats up and down, optionally, joints movable relative to the first cold plate 35 may be provided at the liquid inlet 351 and the liquid outlet 352 of the first cold plate 35. In this way, if the first cold plate 35 or a heat conduction material (such as heat dissipating silicone grease and liquid gold) provided between the first chip 21 and the first cold plate 35 undergoes thermal expansion and contraction, which causes the first cold plate 35 to float up and down, the movable joints can adjust the positions thereof relative to the first cold plate 35, thereby adjusting the positions of the first connecting pipe 333, the second connecting pipe 334 and the third connecting pipe 335, so that the situation that the first connecting pipe 333, the second connecting pipe 334 and the third connecting pipe 335 are pulled to fall off can be effectively avoided, and the connection between the first connecting pipe 333, the second connecting pipe 334 and the third connecting pipe 335 and the first cold plate 35 is relatively reliable.

In order to improve a heat conduction effect between the first cold plate 35 and the first chip 21, optionally, a phase change material (PCM) or heat conduction silicone grease may be provided between the first cold plate 35 and the first chip 21, and the PCM material or the heat conduction silicone grease filled between the first cold plate 35 and the first chip 21 has a relatively high specific heat capacity and a relatively high heat transfer speed, so as to improve the heat dissipation effect of the first cold plate 35 on the first chip 21.

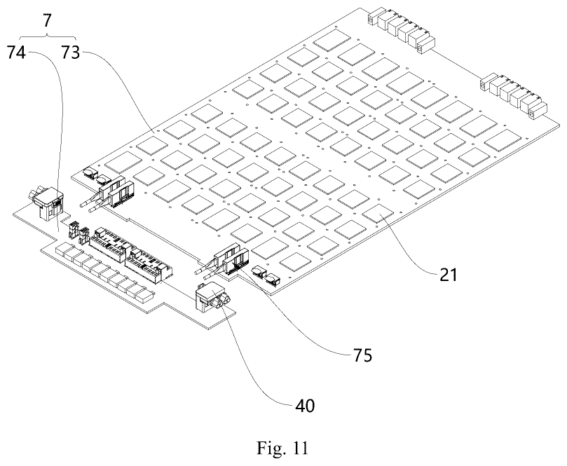

In addition, in order to supply power to the plurality of first chips 21 described above, optionally, as shown in FIG. 11 to FIG. 13, the above server node 1000 may further include a circuit board 7 and a plurality of power components 8, each of the power components 8 is correspondingly provided with a first chip 21, and the power component 8 is used for supplying electric energy to the first chip 21.

The specific arrangement mode of the first chips 21 and the power components 8 on the circuit board 7 is also not limited in the present disclosure, and as one embodiment of the present disclosure, as shown in FIG. 12 and FIG. 13, the above circuit board 7 has a first surface 71 and a second surface 72 which are opposite to each other, the plurality of first chips 21 are located on the first surface 71, and the plurality of power components 8 are located on the second surface 72. In other words, the plurality of first chips 21 and the plurality of power components 8 are respectively located on two opposite sides of the circuit board 7. By utilizing the first surface 71 and the second surface 72 of the circuit board 7 for arranging the plurality of first chips 21 and the plurality of power components 8, a reasonable arrangement of the plurality of first chips 21 and the plurality of power components 8 on the circuit board 7 with a limited area can be achieved, and the high-density reasonable layout of the components in the server node 1000 can be achieved.

Optionally, the above server node 1000 may further include a cooling structure 9, the cooling structure 9 is in communication with the liquid inlet module 4 and the liquid outlet module 5, and the cooling structure 9 is in heat conduction contact with the plurality of power components 8 to cool the power components 8. The cooling structure 9 can have the heat dissipation effect on the power components 8, thereby effectively avoiding the situation that the normal use of the first chip 21 is affected as the power component 8 is in a too high temperature to normally supply power to the first chip 21. In addition, the cooling structure 9 and the liquid cooling module 3 both distribute the cooling liquid through the liquid inlet module 4, and the cooling structure 9 and the liquid cooling module 3 both gather the cooling liquid through the liquid outlet module 5, so that a structure required for distributing the cooling liquid or gathering the cooling liquid can be simplified, preventing the space in the housing 1 from from being excessively occupied.

Optionally, the circuit board 7 is located between the liquid inlet module 4 and the liquid outlet module 5, so as to facilitate the connection of the liquid cooling module 3 and the cooling structure 9, which are respectively located on two sides of the circuit board 7, with the liquid inlet module 4 and the liquid outlet module 5.

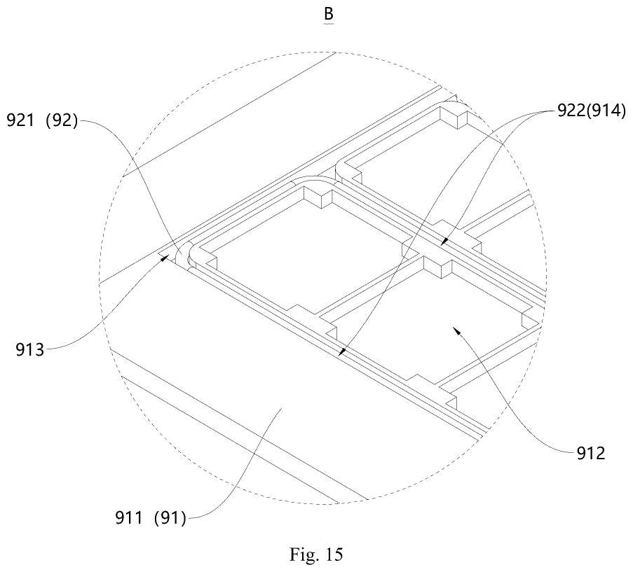

The specific structure of the above cooling structure 9 is also not limited in the present disclosure, and as one embodiment of the present disclosure, as shown in FIG. 14 and FIG. 15, the above cooling structure 9 includes a cooling plate 91 and a cooling channel 92 provided in the cooling plate 91, and the cooling plate 91 is located on a side of the power component 8 facing away from the circuit board 7. The cooling plate 91 includes a plate body 911 and a plurality of accommodating grooves 912 formed in the plate body 911, openings of the accommodating grooves 912 face the circuit board 7, the plurality of accommodating grooves 912 are provided in one-to-one correspondence with the plurality of power components 8, each of the power components 8 is accommodated in the corresponding accommodating groove 912 and is in heat conduction contact with a groove wall of the accommodating groove 912, and the plate body 911 is attached to the circuit board 7.

On the one hand, the cooling plate 91 can have the heat dissipation effect on the power components 8 and the first chips 21 provided on the circuit board 7; on the other hand, the plate body 911 attached to the circuit board 7 can also have a supporting effect on the circuit board 7; and on another hand, the cooling plate 91 can also have an auxiliary heat dissipation effect on the circuit board 7 and the first chips 21 on the circuit board 7.

In order to improve the heat dissipation effect of the cooling plate 91 on the power components 8, optionally, as shown in FIG. 14 and FIG. 15, the above cooling channel 92 is formed as a serpentine channel 921 and includes a plurality of channel sections 922, and two opposite sides of each of the accommodating grooves 912 is provided with a channel section 922. Since the two opposite sides of each of the accommodating grooves 912 is provided the channel section 922, in this way, the channel section 922 of the serpentine channel 921 can be close to the accommodating grooves 912, thereby improving the heat dissipation effect of the power components 8.

In order to ensure that the cooling plate 91 can be always in heat conduction contact with the power component 8, optionally, a heat conduction pad may also be provided between the above cooling plate 91 and the power component 8, and the heat conduction pad can fill a gap between the cooling plate 91 and the power component 8, thereby ensuring that the heat of the power component 8 can be transferred to the cooling plate 91 through the heat conduction pad.

Optionally, as shown in FIG. 14 and FIG. 15, the above cooling plate 91 may include a plurality of groove sets arranged side by side along the length direction of the housing 1, and each of the groove sets includes a plurality of accommodating grooves 912 arranged at intervals along the width direction of the housing. The serpentine channel 921 passes around the plurality of groove sets in sequence.

Optionally, as shown in FIG. 14 and FIG. 15, sections of the above serpentine channel 921 include a first serpentine section 923 and a second serpentine section 924, wherein an inlet of the first serpentine section 923 is in communication with the first joint 42 of the liquid inlet module 4, an inlet of the second serpentine section 924 is in communication with the second joint 43 of the liquid inlet module 4, and outlets of the first serpentine section 923 and the second serpentine section 924 are both in communication with the third joint 52 of the liquid outlet module 5.

In the present disclosure, channels in the cooling plate 91 may be of various types, for example, a cooling pipe 914 may be embedded in the cooling plate 91, or the channel may be provided in the cooling plate 91, which is not limited in the present disclosure. As one embodiment of the present disclosure, as shown in FIG. 14 and FIG. 15, the above cooling plate 91 is provided with a groove 913 with an opening facing towards the circuit board 7, the cooling pipe 914 is embedded in the groove 913, and an internal channel of the cooling pipe 914 is the above cooling channel 92. The cooling pipe 914 embedded in the groove 913 of the cooling plate 91 is relatively simple to machine, thereby being conducive to reducing the machining difficulty of the entire cooling plate 91.

In addition, since the opening of the groove 913 faces towards the circuit board 7, the cooling pipe 914 can also be in contact with the circuit board 7, so as to have the auxiliary heat dissipation effect on the circuit board 7 and the first chips 21 on the circuit board 7, so that the first chips 21 have better heat dissipation effects.

Optionally, as shown in FIG. 2 to FIG. 7, the liquid cooling module 3 is located on a side of the first chip 21 facing away from the circuit board 7, and the cooling structure 9 is located on a side of the power component 8 facing away from the circuit board 7. The server node 1000 further includes a fastener 10, wherein the fastener 10 passes through the liquid cooling module 3 and the circuit board 7 to be connected with the cooling structure 9, so that the first chip 21, the circuit board 7 and the power component 8 can be clamped between the liquid cooling module 3 and the cooling structure 9. The fastener 10 can fix the cooling structure 9 and the liquid cooling module 3 on the circuit board 7 simultaneously, without needing to separately fix the liquid cooling module 3 and the cooling structure 9 by adopting a plurality of fastening structures, so that the assembly complexity can be reduced, and the manufacturing cost can be reduced.

Optionally, as shown in FIG. 7 and FIG. 10, the cooling plate 91 of the above cooling structure 9 is provided with a blind threaded hole, and the fastener 10 can pass through the supporting board 37 of the liquid cooling module 3 and the circuit board 7 to be in threaded connection with the blind threaded hole.

In order to reduce the stress concentration of the first chips 21, optionally, a plurality of fasteners 10 are provided around the periphery of each of the first chips 21, and the plurality of fasteners 10 can apply compressing forces to a plurality of directions of the supporting board 37 simultaneously, so as to compress the first cold plate 35 on the first chips 21, and the first chips 21 have relatively balanced stress and relatively small stress concentration, thereby being not likely to be damaged.

In addition, optionally, as shown in FIG. 2 to FIG. 4, the above server node 1000 further includes a conductive wire 20, wherein at least part of the conductive wire 20 and the liquid inlet module 4 are located between the plurality of chip units 2 and a side wall of the housing 1; and/or at least part of the conductive wire 20 and the liquid outlet module 5 are located between the plurality of chip units 2 and the side wall of the housing 1.

By arranging at least part of the conductive wire 20 and the liquid inlet module 4, or at least part of the conductive wire 20 and the liquid outlet module 5 between the plurality of chip units 2 and the side wall of the housing 1, a space utilization rate of the housing 1 can be increased, thereby being convenient to arrange other components in the server node 1000.

In order to connect electrical components (such as the first chips 21 and the power components 8) in the server node 1000 with an external power supply device, optionally, as shown in FIG. 1 to FIG. 4, and FIG. 8, the above server node 1000 further includes a first power connector 30 and a second power connector 40, wherein the first power connector 30 is provided on a side of the housing 1 and used for being in connection with the external power supply device, and the second power connector 40 is provided on the circuit board 7 of the server node 1000 and used for supplying power to the circuit board 7. The above conductive wire 20 includes a power wire connected between the first power connector 30 and the second power connector 40, wherein at least part of the power wire and the liquid inlet module 4 are located between the plurality of chip units 2 and the side wall of the housing 1; and/or at least part of the power wire and the liquid outlet module 5 are located between the plurality of chip units 2 and the side wall of the housing 1.

Optionally, as shown in FIG. 2 to FIG. 4, the first power connector 30, the first connecting terminal 441 and the second connecting terminal 531 are provided on the same side of the housing 1, in this way, by reasonably designing the shapes of the first power connector 30, the first connecting terminal 441 and the second connecting terminal 531, and the isolation between the first power connector 30, the first connecting terminal 441 and the second connecting terminal 531, the electrohydraulic blind insertion of the server node 1000 can be achieved.

Optionally, as shown in FIG. 2 to FIG. 4, the above server node 1000 may further include a network card 50, an I/O input/output interface 70 and a fan 80. The network card 50 and the I/O input/output interface 70 can achieve information exchange between the server node 1000 and an external device, and the fan 80 is used for generating airflow in the housing 1, so as to air-cool the network card 50.

Optionally, as shown in FIG. 2 to FIG. 4, the above server node 1000 further includes a second chip 90 and a second cold plate 100, wherein the second chip 90 is located on sides of the plurality of chip units 2 in the length direction of the housing 1, the second cold plate 100 covers the second chip 90 and is in heat conduction contact with the second chip 90, and the liquid inlet module 4 and the liquid outlet module 5 are both in communication with the second cold plate 100. The liquid inlet module 4 can also distribute the cooling liquid to the second cold plate 100, so that the second cold plate 100 liquid-cools the second chip 90, and the temperature of the second chip 90 is not excessively high, thereby being conducive to ensuring the normal running of the second chip 90, and prolonging the service life of the second chip 90.

Optionally, the above server node 1000 may further include a network card 50 and a third cold plate, wherein the network card 50 is located on a side of the plurality of chip units 2 in the length direction of the housing 1, the third cold plate covers the network card 50 and is in heat conduction contact with the network card 50, and the liquid inlet module 4 and the liquid outlet module 5 are both in communication with the third cold plate. The network card 50 in the server node 1000 may also dissipate heat through the third cold plate, and during use, the temperature of the network card 50 is not excessively high, thereby being conducive to ensuring the normal running of the network card 50, and prolonging the service life of the network card 50.

Herein, it can be understood that with regard to the embodiment in which the second chip 90 is liquid-cooled through the second cold plate 100, and the network card 50 is also liquid-cooled through the third cold plate, the first chip 21, the second chip 90 and the network card 50 in the server node 1000 all dissipate heat in a liquid cooling manner, and under this circumstance, the heat dissipation of the first chip 21, the second chip 90 and the network card 50 may also be achieved without providing the fan in the housing 1 of the server node 1000. Compared with the embodiment in which some components dissipate heat by adopting the fans, on the one hand, the server node 1000 in a full liquid cooling heat dissipation manner can further save the space in the housing 1 to be convenient to arrange other parts or components of the server node 1000 in the housing 1, and conducive to further improving the arrangement density of various components in the server node 1000; and on the other hand, the server node 1000 can save electric energy and improve the energy saving property of the server node 1000.

In the present disclosure, the circuit board 7 may be integrally formed, and the circuit board 7 may also be formed by splicing a plurality of boards, as long as the circuit board 7 can satisfy the arrangement requirements of various components in the server node 1000, which is not limited in the present disclosure. As one embodiment of the present disclosure, as shown in FIG. 11, the above circuit board 7 includes a chip mainboard 73 and a power distribution board 74 which are arranged side by side, the chip mainboard 73 is detachably in communication with the power distribution board 74, and the plurality of first chips 21 are provided on the chip mainboard 73. In this way, if one of the chip mainboard 73 and the power distribution board 74 fails during use, the chip mainboard 73 or the power distribution board 74 may be separately repaired or replaced without detaching the entire circuit board 7, thereby being convenient for maintenance.

In the present disclosure, the chip mainboard 73 and the power distribution board 74 may be connected in any suitable manner, which is not limited in the present disclosure. As one embodiment of the present disclosure, the chip mainboard 73 and the power distribution board 74 described above may be connected by a board-to-board connector 75. The board-to-board connector 75 can achieve electrical connection and signal transmission between the chip mainboard 73 and the power distribution board 74, so as to satisfy the usage requirements of the circuit board 7.

As other embodiments of the present disclosure, the chip mainboard 73 and the power distribution board 74 described above may also be connected by a flexible printed circuit (namely, FPC), which is not limited in the present disclosure. Optionally, the server node 1000 may further include a fourth cold plate 110, wherein the plurality of first chips 21 are provided on the circuit board 7, the fourth cold plate 110 covers at least part of the circuit board 7 and is in heat conduction contact with the at least part of the circuit board 7, and the liquid inlet module 4 and the liquid outlet module 5 are both in communication with the fourth cold plate 110. In this way, at least part of the circuit board 7 may be cooled in the liquid cooling manner, thereby being helpful in achieving full liquid cooling heat dissipation in the server node 1000.

Optionally, the fourth cold plate 110 covers at least part of the power distribution board 74 and is in heat conduction contact with at least part of the power distribution board 74, and the fourth cold plate 110 can dissipate heat for at least part of the power distribution board 74, thereby ensuring the normal running of the power distribution board 74. Optionally, as shown in FIG. 2 to FIG. 4, the above second cold plate 100 is correspondingly provided with a third liquid conveying pipe 101 and a third liquid discharging pipe 102, wherein the third liquid conveying pipe 101 and the third liquid discharging pipe 102 are respectively provided on two sides of the second cold plate 100 along the width direction of the housing 1, the third liquid conveying pipe 101 is connected with the second joint 43 of the liquid inlet module 4, and the third liquid discharging pipe 102 is connected with the third joint 52 of the liquid outlet module 5. In this way, the cooling liquid can be circulated in the second cold plate 100, and the heat dissipation effect of the second cold plate 100 is better.

As one embodiment of the present disclosure, the above first chip 21 is a computing chip and the second chip 90 is a switching chip. The first chip 21 can handle complex mathematical and logical operations, and the second chip 90 can implement forwarding and routing decisions of data packets, so as to satisfy the usage requirements of the server node 1000.

In one embodiment provided by the present disclosure, as shown in FIG. 2 to FIG. 4, two network cards 50 are provided at intervals along the width direction of the housing 1, the second chip 90 and the second cold plate 100 are arranged between the two network cards 50, and the fan 80 is provided between the network cards 50 and the plurality of chip units 2.

Optionally, the above housing 1 is further provided with a plug-in power-assisted wrench. In this way, the above server node 1000 can be conveniently installed in a cabinet of the server or removed from the cabinet of the server by operating the plug-in power-assisted wrench, thereby being conducive to improving the efficiency of detaching and installing the server node 1000.

The overall size of the server node 1000 is not limited in the present disclosure, the height of the server node 1000 may be 1 Unit or 2 Unit, and the width of the server node 1000 may be 19 inches or 21 inches.

In summary, due to the reasonable arrangement and high degree of compactness of various components in the above server node 1000 provided by the present disclosure, the deployment of a plurality of chips can be achieved in the server node 1000 with the height of 1 Unit and the width of 21 inches, and the heat dissipation of the plurality of chips can also be achieved. That is, the present disclosure can provide the server node 1000 having a relatively small size, but relatively high overall computing power and relatively high computing power density.

According to a second aspect of the present announcement, a server is provided, including the server node 1000 as described above. The server has all of the beneficial effects of the server node 1000 described above, which will not be described in detail herein.

Optionally, the above server may further include a cabinet, and the server node 1000 is provided in the cabinet.

According to a third aspect of the present disclosure, a data center is provided, including the server as described above. The data center has all of the beneficial effects of the above server, which will not be described in detail herein.

The preferred embodiments of the present disclosure have been described in detail with reference to the accompanying drawings. However, the present disclosure is not limited to the specific details in the above embodiments, various simple modifications may be made to the technical solutions of the present disclosure within the scope of the technical concept of the present disclosure, and these simple modifications all fall within the scope of protection of the present disclosure.

In addition, it should be noted that various specific technical features described in the above specific embodiments may be combined in any suitable manner without contradictions, and in order to avoid unnecessary repetition, various possible combination manners will not be separately explained in the present disclosure.

In addition, any combination of various different embodiments of the present disclosure may also be made without departing from the spirit of the present disclosure, which should also be regarded as the content disclosed in the present disclosure.

1. A server node, comprising:
a housing, and
a plurality of chip units, a plurality of liquid cooling modules, a liquid inlet module and a liquid outlet module which are all provided in the housing,
wherein each of the plurality of chip units comprises a plurality of first chips;
the plurality of chip units and the plurality of liquid cooling modules are provided in one-to-one correspondence, each of the plurality of liquid cooling modules is in heat conduction contact with the plurality of first chips in a corresponding chip unit to cool the plurality of first chips; and
the liquid inlet module and the liquid outlet module are provided at intervals along a width direction of the housing, the plurality of chip units and the plurality of liquid cooling modules are located between the liquid inlet module and the liquid outlet module, and each of the plurality of liquid cooling modules is in communication with both the liquid inlet module and the liquid outlet module.

2. The server node according to claim 1, wherein the plurality of chip units comprise a first chip unit and a second chip unit which are arranged side by side along the width direction of the housing and form a chip set;
the plurality of liquid cooling modules comprise a first liquid cooling module corresponding to the first chip unit and a second liquid cooling module corresponding to the second chip unit; and
the first liquid cooling module is correspondingly provided with a first liquid conveying pipe and a first liquid discharging pipe, the second liquid cooling module is correspondingly provided with a second liquid conveying pipe and a second liquid discharging pipe, the first liquid conveying pipe connects the liquid inlet module to the first liquid cooling module, the first liquid discharging pipe connects the first liquid cooling module to the liquid outlet module, the second liquid conveying pipe connects the liquid inlet module to the second liquid cooling module, and the second liquid discharging pipe connects the second liquid cooling module to the liquid outlet module.

3. The server node according to claim 2, wherein the first liquid conveying pipe and the first liquid discharging pipe are provided at intervals along a length direction of the housing, and the first chip unit and the first liquid cooling module are located between the first liquid conveying pipe and the first liquid discharging pipe; and
the second liquid conveying pipe and the second liquid discharging pipe are provided at intervals along the length direction of the housing, and the second chip unit and the second liquid cooling module are located between the second liquid conveying pipe and the second liquid discharging pipe.

4. The server node according to claim 2, wherein the first liquid conveying pipe and the second liquid conveying pipe are on a same side of the chip set, and the first liquid conveying pipe and the second liquid conveying pipe are arranged along a height direction of the housing; and
the first liquid discharging pipe and the second liquid discharging pipe are on a same side of the chip set, and the first liquid discharging pipe and the second liquid discharging pipe are arranged along the height direction of the housing.

5. The server node according to claim 4, wherein the first liquid cooling module and the second liquid cooling module each comprise a flow shunting structure, a flow collecting structure and a plurality of first cold plates, each of the plurality of first cold plates is in heat conduction contact with at least one first chip, the flow shunting structure is in communication with a plurality of corresponding first cold plates, and the flow collecting structure is in communication with a plurality of corresponding first cold plates;
the first liquid conveying pipe is connected with the flow shunting structure of the first liquid cooling module, the first liquid discharging pipe is connected with the flow collecting structure of the first liquid cooling module, the second liquid conveying pipe is connected with the flow shunting structure of the second liquid cooling module, and the second liquid discharging pipe is connected with the flow collecting structure of the second liquid cooling module;
the flow shunting structure of the first liquid cooling module and the flow shunting structure of the second liquid cooling module are at a same height, and the flow shunting structure of the first liquid cooling module and the flow shunting structure of the second liquid cooling module are between the first liquid conveying pipe and the second liquid conveying pipe; and
the flow collecting structure of the first liquid cooling module and the flow collecting structure of the second liquid cooling module are at a same height, and the flow collecting structure of the first liquid cooling module and the flow collecting structure of the second liquid cooling module are between the first liquid discharging pipe and the second liquid discharging pipe.

6. The server node according to claim 2, wherein a plurality of chip sets are provided, and the plurality of chip sets are provided side by side along a length direction of the housing.

7. The server node according to claim 6, wherein the plurality of chip sets comprise a first chip set and a second chip set; a first liquid conveying pipe corresponding to a first chip unit of the first chip set, a second liquid conveying pipe corresponding to a second chip unit of the first chip set, a first liquid conveying pipe corresponding to a first chip unit of the second chip set, and a second liquid conveying pipe corresponding to a second chip unit of the second chip set are all located between the first chip set and the second chip set; and
a first liquid discharging pipe corresponding to the first chip unit of the first chip set and a second liquid discharging pipe corresponding to the second chip unit of the first chip set are located on a side of the first chip set facing away from the second chip set, and a first liquid discharging pipe corresponding to the first chip unit of the second chip set and a second liquid discharging pipe corresponding to the second chip unit of the second chip set are located on a side of the second chip set facing away from the first chip set.

8. The server node according to claim 7, wherein the liquid inlet module comprises a liquid inlet pipe, a first joint and a second joint, the first joint and the second joint are both in communication with the liquid inlet pipe, the first joint is located on a side of the first chip set, and the second joint is located on a side of the second chip set;
the first liquid conveying pipe corresponding to the first chip unit of the first chip set and the second liquid conveying pipe corresponding to the second chip unit of the first chip set are both connected with a side of the first joint close to the second joint;
the first liquid conveying pipe corresponding to the first chip unit of the second chip set and the second liquid conveying pipe corresponding to the second chip unit of the second chip set are both connected with a side of the second joint close to the first joint; and
the liquid outlet module comprises a liquid outlet pipe and a third joint, the liquid outlet pipe is in communication with the third joint, the first liquid discharging pipe corresponding to the first chip unit of the first chip set and the second liquid discharging pipe corresponding to the second chip unit of the first chip set are both connected with a side of the third joint, and the first liquid discharging pipe corresponding to the first chip unit of the second chip set and the second liquid discharging pipe corresponding to the second chip unit of the second chip set are both connected with another side of the third joint.

9. The server node according to claim 8, wherein the liquid inlet module further comprises a liquid distributor, a first liquid distribution pipe and a second liquid distribution pipe,
the liquid distributor is between the first joint and the second joint, the liquid inlet pipe is in communication with the liquid distributor, the liquid distributor is in communication with the first joint through the first liquid distribution pipe, and the liquid distributor is in communication with the second joint through the second liquid distribution pipe.

10. The server node according to claim 1, wherein each of the liquid cooling modules comprises a plurality of first cold plates, the plurality of first cold plates of each liquid cooling module are in one-to-one correspondence with the plurality of first chips of the chip unit corresponding to the each liquid cooling module, and each of the plurality of first cold plates covers a first chip corresponding to the each cold plate;
the plurality of first cold plates of each of the plurality of liquid cooling modules are arranged in a plurality of cooling sets side by side along a first direction, each of the plurality of cooling sets comprises multiple first cold plates side by side along a second direction perpendicular to the first direction, the plurality of cooling sets of each of the liquid cooling modules are connected in parallel with each other, and the multiple first cold plates of each of the plurality of cooling sets are connected in series with each other; and
the liquid inlet module is in communication with a first cold plate at a most upstream position in each of the plurality of cooling sets, and a first cold plate at a most downstream position in each of the plurality of cooling sets is in communication with the liquid outlet module.

11. The server node according to claim 10, wherein each of the plurality of liquid cooling modules comprises a flow shunting structure and a flow collecting structure, the flow shunting structure is in communication with the liquid inlet module, and the flow collecting structure is in communication with the liquid outlet module; and
for each of the plurality of liquid cooling modules, the flow shunting structure and the flow collecting structure are provided at intervals along the second direction, and the plurality of cooling sets are located between the flow shunting structure and the flow collecting structure;
a liquid inlet of a first cold plate closest to the flow shunting structure in each of the plurality of cooling sets is connected with the flow shunting structure through a first connecting pipe, liquid outlets and liquid inlets of two adjacent first cold plates in each of the plurality of cooling sets are connected through a second connecting pipe, and a liquid outlet of a first cold plate closest to the flow collecting structure in each of the plurality of cooling sets is connected with the flow collecting structure through a third connecting pipe.

12. The server node according to claim 10, wherein each of the plurality of liquid cooling modules comprises a supporting board, and each of the plurality of first cold plates is provided with a plurality of mounting lugs;
each of the plurality of mounting lugs is penetrated with a fastening bolt which is connected with the supporting board, the fastening bolt is sleeved with an elastic member, one end of the elastic member abuts against the each mounting lug, and another end of the elastic member abuts against a head of the fastening bolt; and
the supporting board has an opening for exposing at least part of each of the plurality of first cold plates to enable the each first cold plate to be in heat conduction contact with a first chip corresponding to the each first cold plate.

13. The server node according to claim 1, further comprising a circuit board, a plurality of power components and a cooling structure,
wherein each of the plurality of power components is correspondingly provided with a first chip, and the each power component is used for supplying electric energy to the first chip;
the circuit board has a first surface and a second surface which are opposite to each other, the plurality of first chips are on the first surface, and the plurality of power components are on the second surface; and
the cooling structure is in communication with the liquid inlet module and the liquid outlet module, and the cooling structure is in heat conduction contact with the plurality of power components to cool the plurality of power components.

14. The server node according to claim 13, wherein the cooling structure comprises a cooling plate and a cooling channel in the cooling plate, and the cooling plate is on a side of the power component facing away from the circuit board;
the cooling plate comprises a plate body which is attached to the circuit board, and a plurality of accommodating grooves in the plate body, with openings of the plurality of accommodating grooves facing the circuit board; and
the plurality of accommodating grooves are in one-to-one correspondence with the plurality of power components, and each of the plurality of power components is accommodated in an accommodating groove corresponding to the each power component, and is in heat conduction contact with a groove wall of the accommodating groove.

15. The server node according to claim 14, wherein the cooling channel is a serpentine channel and comprises a plurality of channel sections, and each of two opposite sides of each of plurality of the accommodating grooves is provided with a channel section.

16. The server node according to claim 1, further comprising a conductive wire,
wherein at least part of the conductive wire and the liquid inlet module are located between the plurality of chip units and a side wall of the housing; and/or,
at least part of the conductive wire and the liquid outlet module are located between the plurality of chip units and the side wall of the housing.

17. The server node according to claim 1, wherein the server node further comprises a second chip and a second cold plate, the second chip is on a side of the plurality of chip units in a length direction of the housing, the second cold plate covers the second chip and is in heat conduction contact with the second chip, and the liquid inlet module and the liquid outlet module are both in communication with the second cold plate; and/or
the server node further comprises a network card and a third cold plate, the network card is located on a side of the plurality of chip units in the length direction of the housing, the third cold plate covers the network card and is in heat conduction contact with the network card, and the liquid inlet module and the liquid outlet module are both in communication with the third cold plate; and/or the server node further comprises a circuit board and a fourth cold plate, the plurality of first chips are on the circuit board, the fourth cold plate covers at least part of the circuit board and is in heat conduction contact with the at least part of the circuit board, and the liquid inlet module and the liquid outlet module are both in communication with the fourth cold plate.

18. The server node according to claim 1, further comprising a circuit board, wherein the circuit board comprises a chip mainboard and a power distribution board which are arranged side by side, the chip mainboard is detachably connected with the power distribution board, and the plurality of first chips are provided on the chip mainboard.

19. A server, comprising the server node according to claim 1.

20. A data center, comprising the server according to claim 19.
